(19) United States
(12) Patent Application Publication
(10) Pub. No.: US 2011/0248128 A1
(43) Pub. Date: Oct. 13, 2011

(54) Low Profile Motorize Tilt Mount

(76) Inventor: Sung I. Oh, West Covina, CA (US)

(21) Appl. No.: 13/080,729

(22) Filed: Apr. 6, 2011

Related U.S. Application Data
(60) Provisional application No. 61/322,861, filed on Apr. 11, 2010.

(51) Int. Cl. H05K 7/16; B23P 19/00

(52) U.S. Cl. 248/201; 29/426.5

(57) ABSTRACT

A mount system is adapted to couple a monitor to a supporting surface. The natural tendency of the mount system is to tilt down the monitor, due to the weight of the monitor. However, the weight of the monitor may be at least partially counter-balanced by having to lift its own weight of the monitor such that less force may be required to tilt the monitor up. A motor may be activated to pull on a string that is coupled adjacent to a top portion of the monitor.

### RELATED APPLICATION

This application claims priority to a provisional application Ser. No. 61/322,861, filed Apr. 11, 2010, which is hereby incorporated by reference.

### BACKGROUND OF THE INVENTION

1. Field of the Invention

This invention is directed to a mount system that is adapted to couple to a back side of a monitor and reposition the viewing angle of the monitor, and in particular, to tilt the monitor through a motorize action.

2. Background of the Invention

Flat panel monitors such as computer monitors, LCD, plasma, slim televisions, and the like (collectively referred to as “monitor(s)”) are becoming popular because they can be mounted onto a wall to save floor space and for their aesthetically pleasing appearance. Moreover, the recent trend is to make the flat screen monitors slim as possible. For instance, some monitors are now about 1.0 inch or less in thickness. And with such slim monitors, it is desirable to mount the monitor close to the wall as possible.

There are a number of manual mounts that anchor the monitor close to the wall and tilts the monitor down for more comfortable viewing angle. However, with the manual tilt mount, a user needs to physically tilt the monitor down when viewing the monitor, and tilt the monitor up when the monitor is turned off. Alternatively, motorize tilt mounts tilts the monitor up and down with the convenience of a remote control but due to the motorize mechanisms incorporated into the motorize mounts, the depth of the motorize mounts may be thicker than the monitor, so that they may not be aesthetically pleasing supporting a slim monitor. Accordingly, there is a need for a low profile tilt mount without the above-mentioned dis-advantages of current mounting solutions.

### INVENTION SUMMARY

This invention is directed to a mount system adapted to couple a monitor to a supporting surface such as a side wall. The natural tendency of the mount system is to tilt down the monitor, due to the weight of the monitor. However, the weight of the monitor may be at least partially counter-balanced by having to lift its own weight of the monitor such that less force may be required to tilt the monitor up. By way of analogy, the mount system may act as an unbalanced seesaw where a first end of the seesaw has a slightly heavier weight than a second end of the seesaw. To lift the first end, a fraction of the weight that is on the first end may be applied to the second end rather than applying a weight that is greater than the weight on the first end. This way, a smaller motor may be used to lift the monitor from the tilt down position. In this regard, the mount system includes: an anchoring bracket adapted to couple to a supporting surface, the anchoring bracket having a first end and a second end; a panel mounting bracket adapted to couple to a rear side of a monitor, the panel mounting bracket having a first end and a second end, the second end of the panel mounting bracket pivotably coupled to the second end of the anchoring bracket about a first axis, the first axis adapted to slide substantially along a vertical axis when in use; a link having a proximal end and a distal end, the proximal end pivotably coupled to the anchoring bracket about a second axis, the distal end pivotably coupled to the panel mounting bracket about a third axis, the second pivot axis closer to the first end of the anchoring bracket than the second end of the anchoring bracket, and third pivot axis closer to the second end of the panel mounting bracket than the first end of the panel mounting bracket; and a motorize gear adapted to pull the first end of the panel mounting bracket relative to the first end of the anchoring bracket.

Other systems, methods, features, and advantages of the invention will be, or will become, apparent to one with skill in the art upon examination of the following figures and detailed description. It is intended that all such additional systems, methods, features, and advantages be included within this description, be within the scope of the invention, and be protected by the following claims.

### BRIEF DESCRIPTION OF THE DRAWINGS

The invention can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 is a perspective view of a mount system for a monitor.

FIG. 2 shows a side view of a mounting bracket in an extended position.

FIG. 3 shows a rear view of the mount system.

FIG. 4 shows a partial view of the mounting bracket of FIG. 2.

FIG. 5 shows a motorize gear system.

FIG. 6 shows a rear perspective view of the gear system of FIG. 5.

FIG. 7 shows a detail assembly perspective view of a slippage gear.

FIG. 8 shows a detail perspective view of a base gear.

FIG. 9 shows a detail perspective view of a cup.

FIG. 10 shows a detail perspective view of the cup and base gear assembly.

FIG. 11 shows a partial view of the cup.

FIG. 12 shows a perspective view of the up.

### DETAILED DESCRIPTION OF THE INVENTION

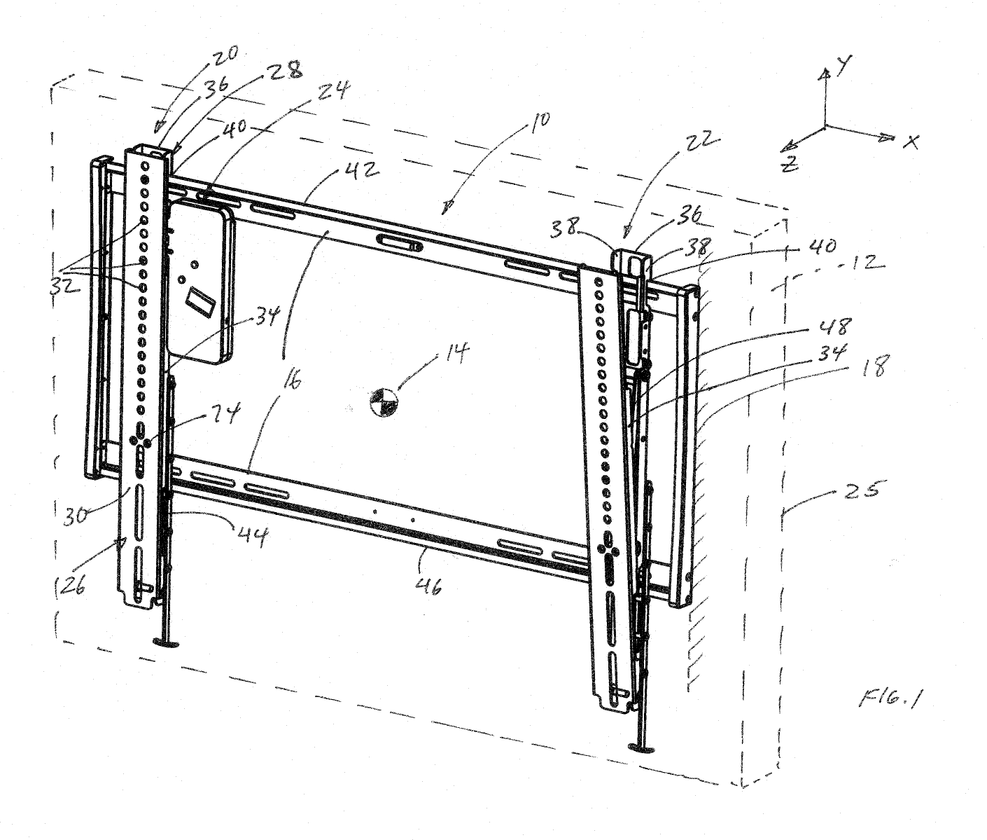

FIG. 1 shows a perspective view of a mount system 10 adapted to pivot a monitor 12 about an X-axis or about YZ plane. The monitor 12 may have a center of gravity 14 about its center and the direction of the gravitational force may be generally along the negative (−) Y-axis. It is, however, within the scope of this invention to have the gravitational force in other directions. The mount system 10 may include an attachment bracket system 16 adapted to couple the mount system 10 to a supporting surface such as a wall 18. The mount system 10 may also include a first mount bracket 20 and a second mount bracket 22 adapted to couple to the rear side 25 of the monitor 12. The first mount bracket 20 may be coupled to a motorize gear system 24 adapted to tilt the bracket 20 via a motorize action. Other than the motorize gear system 24, the first and second mount brackets 20 and 22 may have similar mechanical mechanisms so for purpose of this description, the first mount bracket 20 will be described in detail below, which would apply to the second mount bracket 22.

The first mounting bracket 20 includes a first panel mounting bracket 26 and a first anchoring bracket 28. Note that FIG. 1 shows the first panel mounting bracket 26 in a retracted position relative to the anchoring bracket 28, and the second mounting bracket 22 in an extended position. The first panel mounting bracket 26 may have a base 30 with a plurality of holes 32 adapted to receive one or more screws to attach to the rear side 25 of the monitor 12. The first panel mounting bracket 26 may also have side walls 34 such that the first panel mounting bracket 26 may form a U-shaped configuration. The anchoring bracket 28 may have a base 36 and side walls 38 forming a U-shaped configuration. The anchoring bracket 28 may have a first hook 40, shown and described in more detail below, adapted to latch onto a first rail 42 of the attachment bracket 16. The anchoring bracket 26 may have a second hook mechanism 44, shown and described in more detail below, adapted to latch onto a second rail 46 of the attachment bracket 16. The first mounting bracket 20 may include a link 48, shown and described in more detail below, located between the first panel mounting bracket 26 and the first anchoring bracket 28.

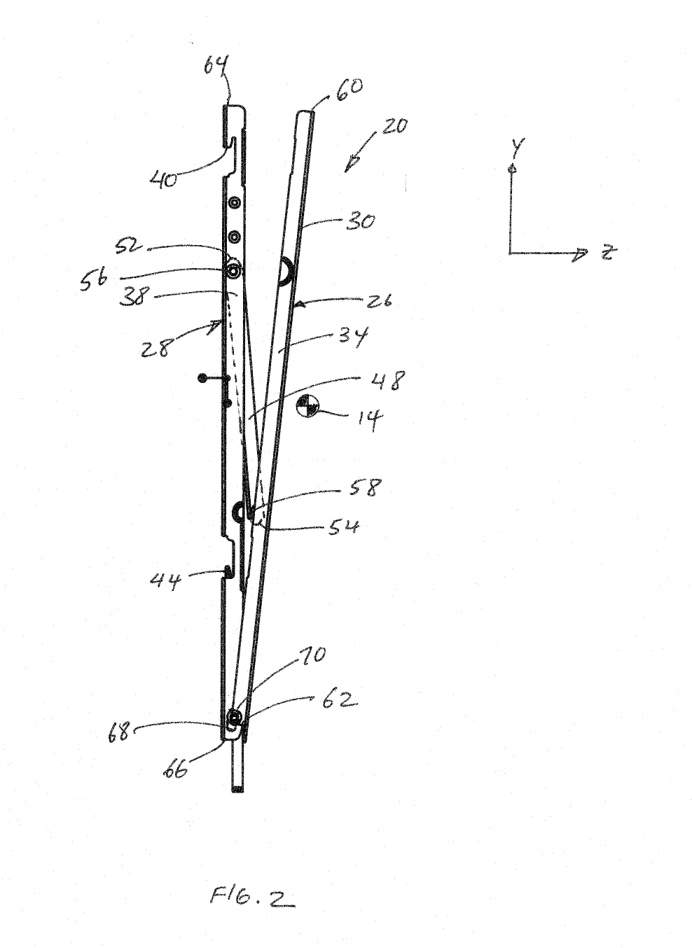

FIG. 2 shows a side view of the first mounting bracket 20 in an extended position. The link 48 has a proximate end 52 and a distal end 54. The proximate end 52 may be adapted to pivotably couple to the anchoring bracket 28 about a first pivot axis 56; and the distal end 54 may be adapted to pivotably couple to the panel mounting bracket 26 about a second pivot axis 58. The panel mounting bracket 26 may have a first end 60 and a second end 62. The anchoring bracket 28 may have a first end 64 and a second end 66. The second end 66 of the anchoring bracket 28 may have an elongated opening 68 where the longitudinal axis of the opening 68 may be generally along the axis Y. The second end 62 of the panel mounting bracket 26 may be pivotably engaged to the elongated opening 68 about a third pivot axis 70. It is within the scope of the invention to have the elongated opening on the second end of the panel mounting bracket 26.

With the link 48 pivotably coupled to the panel mounting bracket 26 and the anchoring bracket 28 as described above, as the panel mounting bracket 26 moves from the retracted position to the extended position, the second pivot axis 58 arcs with the focal point being the first pivot axis 56 such that the second pivot axis 58 moves along the positive (+) YZ plane. Thereby causing the center of gravity 14 of the monitor 12 to shift towards the positive Y and Z axes. This in turn causes, the third pivot axis 70 to move generally in the positive (+) Y-axis direction; and in return, moves the third pivot axis 70 generally in the negative (−) Y-axis when the panel mounting bracket moves from the extended position to the retracted position.

In this example, the gravitational force “g” may be in the −Y direction. When the panel mounting bracket 26 is in a retracted position, its natural tendency is to extend or tilt down due to the weight of the monitor. With the first link 48 arranged as discussed above, in order for the panel mounting bracket 26 to extend or tilt, the third pivot axis 70 needs to move in the +Y direction or be lifted against the direction of the gravitational force “g”. At the same time, the weight of the monitor applies downward force on the third pivot axis 70 to resist against extending or tilting the panel mounting bracket 26. With the link 48 pivotably coupling the first panel mounting bracket 26 to the first anchoring bracket 28, as discussed above, the natural tendency is to tilt down the monitor, due to the weight of the monitor. However, the weight of the monitor may be at least partially counter-balanced by having to lift its own weight of the monitor in the positive Y-axis such that less force may be required to move the monitor from the extended position to the retracted position relative to a monitor being tilt about a fixed pivot axis.

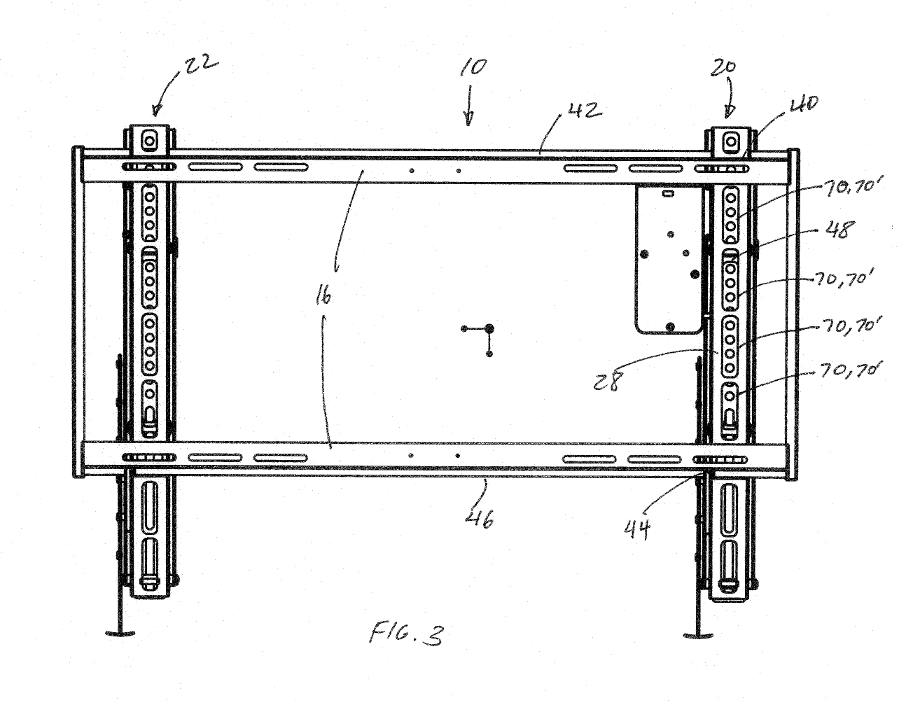

FIG. 3 shows a rear view of the mount system 10 illustrating the first and second hooks 40 and 44 anchoring to the first and second rails 42 and 46, respectively. The anchoring bracket 28 and the link 48 may have a plurality of openings 70 and 70′, which align with respect to each other so that a screw driver may pass through both openings 70 and 70 to insert a screw through the holes 32 to couple the panel mounting bracket 26 to the rear side 25 of the monitor 12.

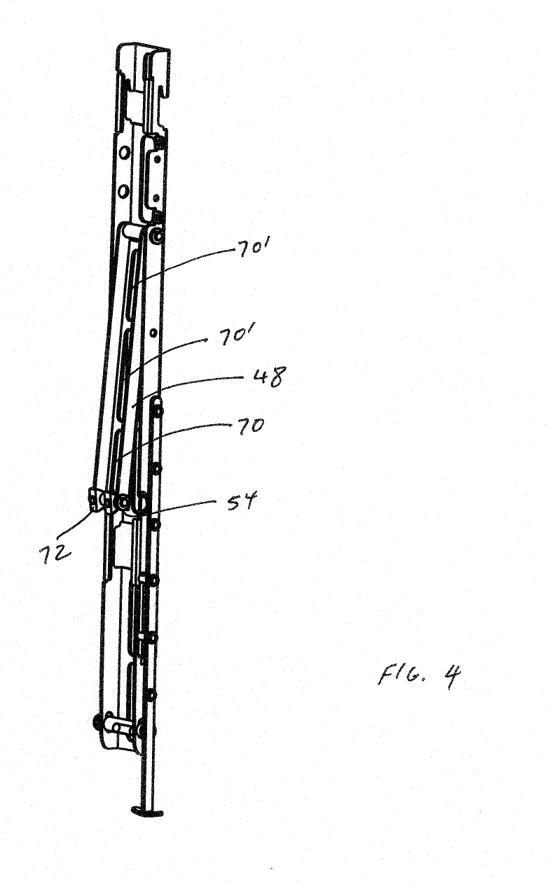

FIG. 4 shows the first mounting bracket 20 without the panel mounting bracket to show the openings 70′ on the link 48. The distal end 54 of the link 48 may be coupled to a hinge bracket 72 that is adapted to couple to the panel mounting bracket 26 at a location 74 shown in FIG. 1.

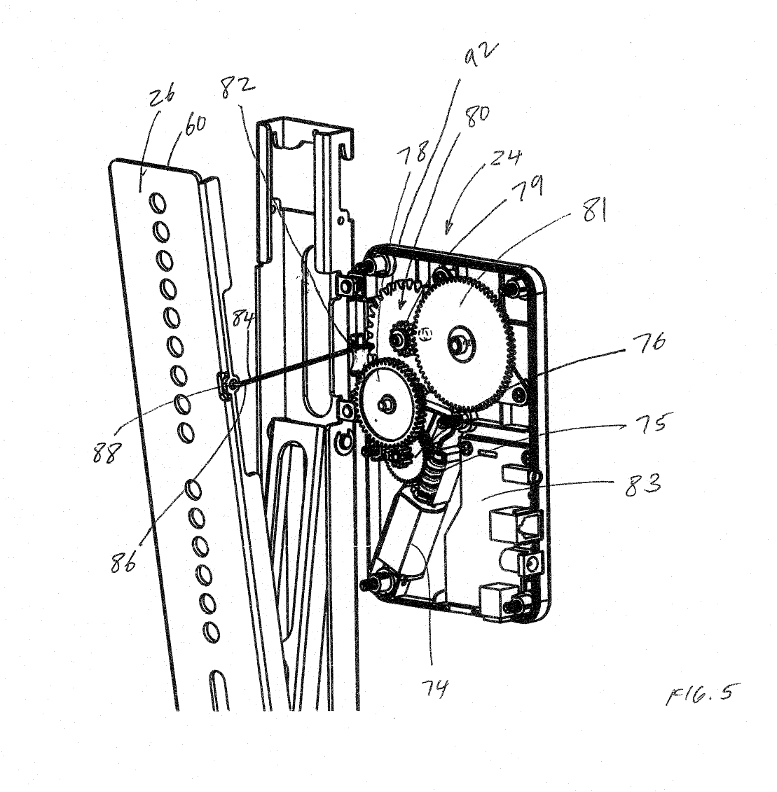

FIG. 5 shows the motorize gear system 24 with the front cover removed. With the mounting bracket 20 described above, less force may be required to move the monitor from the extended position to the retracted position in comparison to a monitor being tilted about a fixed pivot axis. As such, less torque may be needed from the motor, which in turn means that a smaller size motor may be used so that the depth of the mount system 10 may be reduced. The gear system 24 may include a motor 74 having a worm gear 75. The worm gear 75 may be mechanically engaged with a first gear 76, which in turn is engaged with a second gear 78, which in turn is engaged with a slippage gear 80 to increase the torque and reduce the speed. The slippage gear 80 may have a third gear 79 as discussed in more detail below. The motorize gear system 24 may also include a roller 82. The slippage gear 80 may act like a spool to release and retract a string 84 that passes over the roller 82. The distal end 86 of the string 84 may be coupled to a hook 88 on the panel mounting bracket 26. The hook 88 may be located adjacent to the first end 60 of the panel mounting bracket 26 so that as the string pulls on the hook 88, the distance between the hook 88 and the center of gravity 14 of the monitor my act as a leverage to tilt the monitor up so that less torque may be required from the motor.

The motorize gear system 24 may also include an encoder wheel 81 that may be engaged with the third gear 79. The encoder wheel 81 may keep track of the rotational position of the third gear 79. The encoder wheel 81 may be communicably couple to a processor 83 so that the processor may determine how much the string 84 has been extended or retracted into the slippage gear 80. This way, the processor may determine if the string 84 is fully extended or fully retracted into the slippage gear.

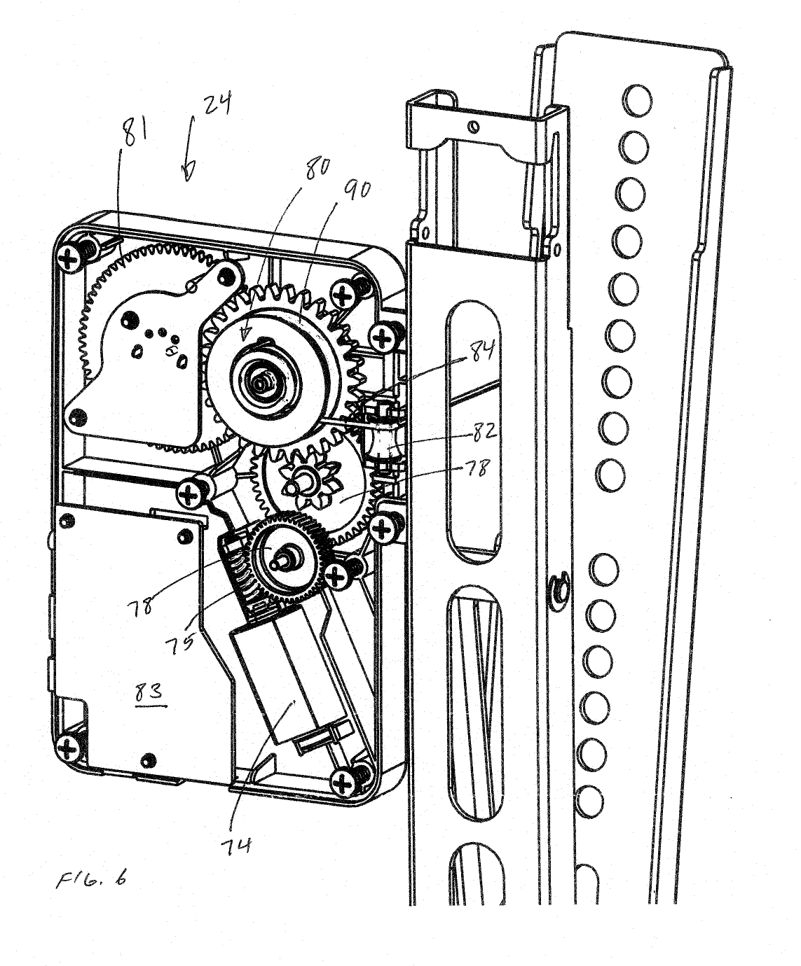

FIG. 6 shows a rear perspective view of the gear system 24 with the back cover removed. The slippage gear 80 may have a side wall 90 having a concave configuration forming a spool like side wall to rolls up the string 84 in order to release and retract the string 84. As such, as the motor 74 releases the string, the weight of the monitor tilts the panel mounting bracket 26 down; however, with the link 48 between the two brackets 26 and 28 described above, less torque is required from the motor 74 to retract the monitor 12 up.

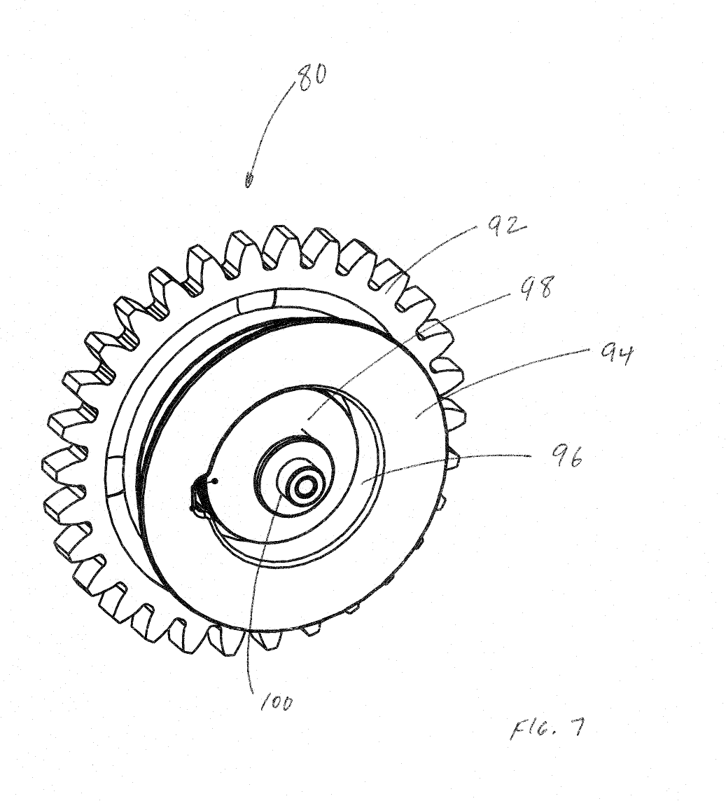

FIG. 7 shows a detail assembly perspective view of the slippage gear 80. The slippage gear may have a base gear 92 releasably engaged with a cup 94 having a cavity 96. The cavity 96 may be adapted to receive one or more spring washers 98. A nut 100 may be used to press the spring washers 98 such that the cup 94 is pressed against the base gear 92.

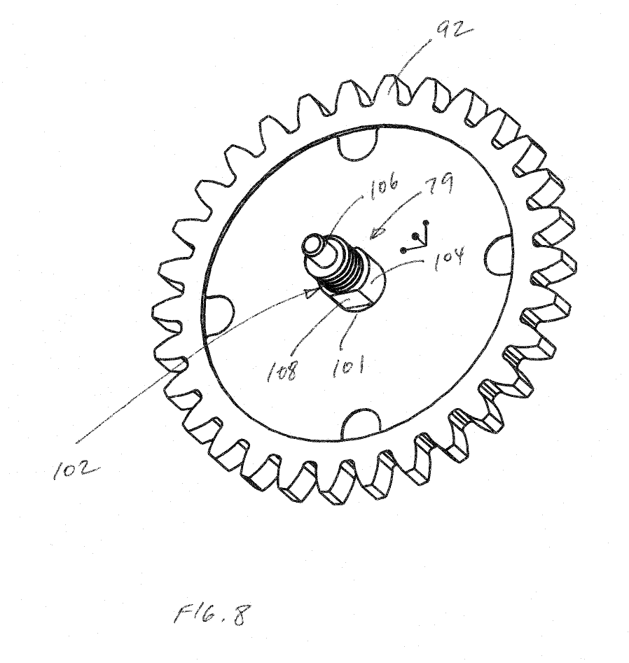

FIG. 8 shows a detail perspective view of the base gear 92. The base gear 92 may have a round opening 101. The third gear 79 may pass through the round opening 101 with a threaded end 102 protruding out of the opening 101. The third gear 79 may have a portion of the shaft 104 having a planner edge 108 passing through the opening 101. This allows the base gear 92 to rotate freely around the shaft 104 of the third gear 79. The third gear 79 may have a tip 106 that engages with the front cover of the motorize gear system 24.

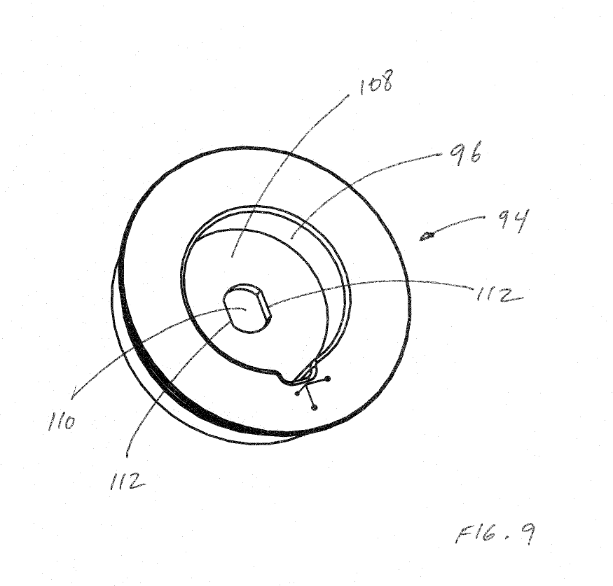

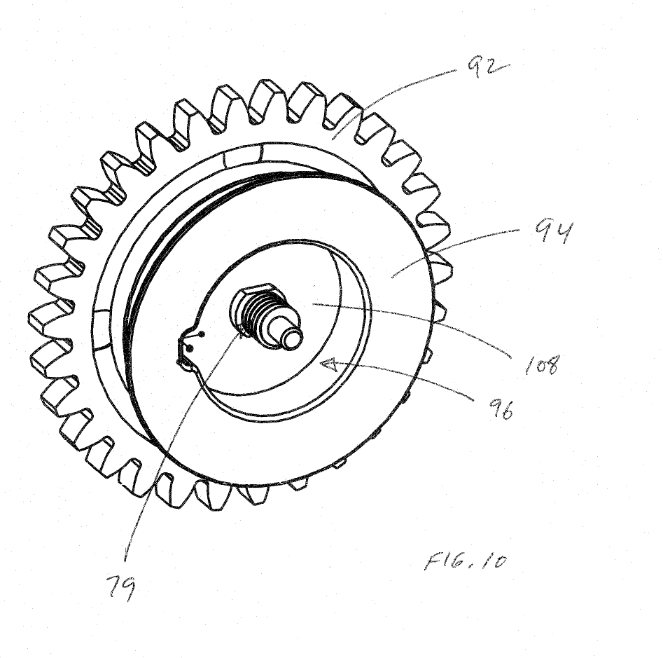

FIG. 9 shows the cup 94 with the cavity 96 with a base 108 having a semi-circular opening 110 with straight edges 112. FIG. 10 shows the cup 94 juxtaposed to the base gear 92 with the shaft 104 portion of the third gear 79 passing through the semi-circular opening 110 such that the third gear 79 and the cup 94 rotate in unison.

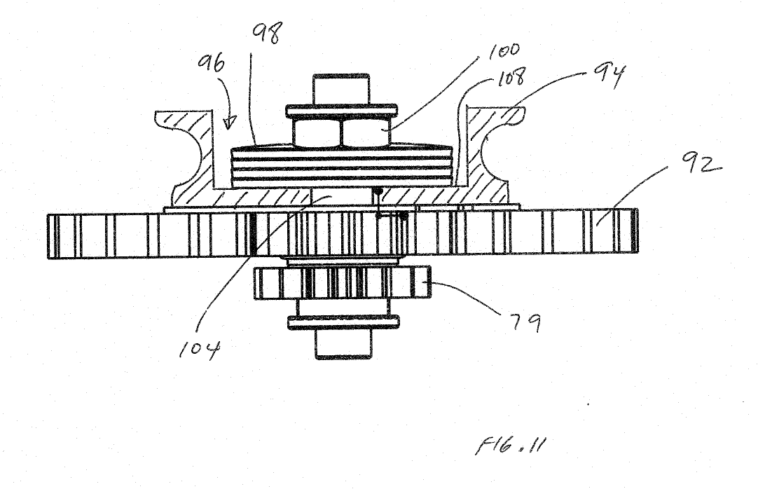

FIG. 11 shows an assembly view of the slippage gear 80 with a cutout view of the cup 94. With the spring washers 98 placed inside the cavity 96, the nut 100 may be tightened over the threaded end 102 to press the spring washers 98. The spring washers 98 presses the base 108 of the cup 94 against the base gear 92 so that the cup 94 may be frictionally engaged with the base gear 92. This allows the cup 94 and the third gear 79 to rotate relative to the base gear 92 if enough torque is applied to the cup 94 to overcome the friction between the cup 94 and the base gear 92. Note that it is within the scope of the invention to use a variety of biasing mechanisms such as a spring to press the cup against the base gear.

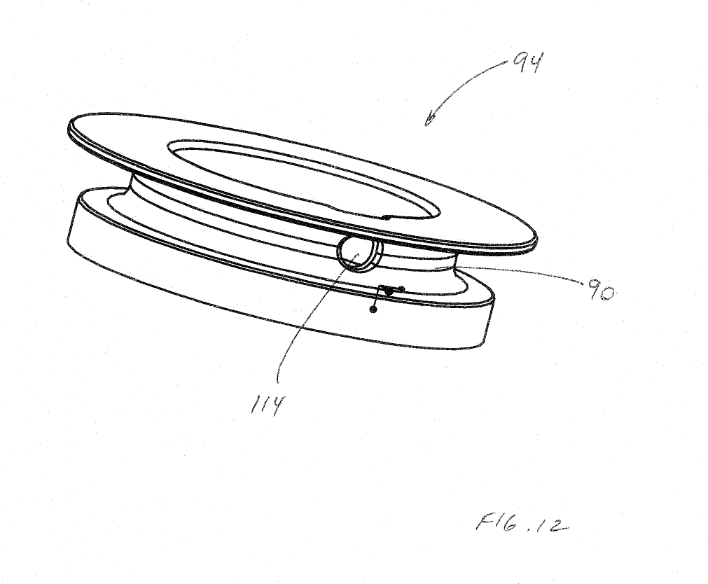

FIG. 12 shows a perspective view of the cup with a hole 114 on the side wall 90. One end of the string 84 may be inserted through the hole 114 and form a knot inside the cavity 96. The side wall 90 has a concave surface to act as a spool to roll up the string 84 around the side wall.

With a slippage gear 80, if a foreign object interferes with the panel mounting bracket 26 such that the foreign object stops the panel mounting bracket from moving up, the string 82 may pull on the cup 94 to stop the cup 94 from rotating while the motor 74 is rotating the base gear 92. As such, the panel mounting bracket may apply less force on the foreign object, and prevent the motor 74 from burning out. In addition, if a user pulls down the TV to manually tilt down the monitor, the string will pull on the cup 94, and if the pulling force on the monitor is strong enough, the pulling force on the string may be strong enough to overcome the friction between the cup 94 and the base gear 92 such that the third gear 79 and the cup 94 may slip or rotate without the base gear 92 rotating. Note that the third gear 79 is engaged with the encoder wheel 81 so that the processor 83 may keep track of how much string has been released from the cup.

While various embodiments of the invention have been described, it will be apparent to those of ordinary skill in the art that many more embodiments and implementations are possible within the scope of this invention. Accordingly, the invention is not to be restricted except in light of the attached claims and their equivalents.

1. A method of tilting a monitor having a weight, the method comprising:
counter-balancing at least a portion of the weigh of the monitor from tilting down; and
pulling on a top portion of the monitor to move the monitor from an extended position to a retracted position.

2. The method according to claim 1, where the step of pulling on the top portion of the monitor is through a string.

3. The method according to claim 1, where the step of pulling is done by a motor.

4. A mount system for tilting a monitor having a weight, the mount system including:
an anchoring bracket adapted to couple to a supporting surface, the anchoring bracket having a first end and a second end;
a panel mounting bracket adapted to couple to a rear side of a monitor, the panel mounting bracket having a first end and a second end, the second end of the panel mounting bracket pivotably coupled to the second end of the anchoring bracket about a first axis, the first axis adapted to slide substantially along a vertical axis when in use;
a link having a proximal end and a distal end, the proximal end pivotably coupled to the anchoring bracket about a second axis, the distal end pivotably coupled to the panel mounting bracket about a third axis, the second pivot axis closer to the first end of the anchoring bracket than the second end of the anchoring bracket, and third pivot axis closer to the second end of the panel mounting bracket than the first end of the panel mounting bracket; and
a motorize gear adapted to pull the first end of the panel mounting bracket relative to the first end of the anchoring bracket.

5. The mount system according to claim 4, where the motorize gear includes a string that is retracted to pull the first end of the panel mounting bracket.

6. The mount system according to claim 5, where the motorize gear includes a motor and a slippage gear, the slippage gear adapted to stop pulling on the panel mounting bracket while the motor is running.
